(19) United States
(12) Patent Application Publication
(10) Pub. No.: US 2022/0066411 A1
(43) Pub. Date: Mar. 3, 2022

(54) DETECTING AND CORRECTING SUBSTRATE PROCESS DRIFT USING MACHINE LEARNING

(71) Applicant: APPLIED MATERIALS, INC., Santa Clara, CA (US)

(72) Inventors: Upendra V. Ummethala, Cupertino, CA (US); Blake Erickson, Gilroy, CA (US); Prashanth Kumar, Union City, CA (US); Michael Kutney, Santa Clara, CA (US); Steven Trey Tindel, Austin, TX (US); Zhaozhao Zhu, Milpitas, CA (US)

(21) Appl. No.: 17/379,728

(22) Filed: Jul. 19, 2021

Related U.S. Application Data
(60) Provisional application No. 63/072,824, filed on Aug. 31, 2020.

(51) Int. Cl. G05B 19/401; G06N 20/00; G06N 5/04

(52) U.S. Cl. CPC G05B 19/401; G06N 20/00; G05B 2219/45031; G05B 2219/34215; G06N 5/04

(57) ABSTRACT

Methods and systems for detecting and correcting substrate process drift using machine learning are provided. Data associated with processing each of a first set of substrates at a manufacturing system according to a process recipe is provided as input to a trained machine learning model. One or more outputs are obtained from the trained machine learning model. An amount of drift of a first set of metrology measurement values for the first set of substrates from a target metrology measurement value is determined from the one or more outputs. Process recipe modification identifying one or more modifications to the process recipe is also determined. For each modification, an indication of a level of confidence that a respective modification to the process recipe satisfies a drift criterion for a second set of substrates is determined. In response to an identification of the respective modification with a level of confidence that satisfies a level of confidence criterion, the process recipe is updated based on the respective modification.

### RELATED APPLICATION

This application claims benefit of U.S. Provisional Patent Application 63/072,824, filed Aug. 31, 2020, the entire content of which is incorporated by reference herein.

### TECHNICAL FIELD

Embodiments of the present disclosure relate, in general, to manufacturing systems and more particularly to detecting and correcting substrate process drift using machine learning.

### BACKGROUND

A process recipe performed at a manufacturing system may be configured to achieve a particular substrate quality and consistency. Components of the manufacturing system may become defective, causing one or more conditions at the manufacturing system to change unexpectedly during the processing of a substrate. If action is not taken to address the defective component (e.g., identifying and replacing the defective component, modifying the process recipe to counteract the impact of the defective component, etc.), errors may result during processing of a substrate and a finished substrate may be defective. Over time, the quality and consistency for substrates processed at the manufacturing system may drift away from the target quality and consistency associated with the process recipe. However, it may be difficult for an operator of the manufacturing system to identify a drift from the target quality and consistency, to determine the defective component that is causing the drift, and determine an appropriate action to address the drift in quality and consistency.

### SUMMARY

Some of the embodiments described cover a system including a memory and a processing device coupled to the memory. The processing device is to provide, as input to a trained machine learning model, data associated with processing each of a first set of substrates at a manufacturing system according to a process recipe. The processing device is further to obtain one or more outputs from the trained machine learning model. The processing device is further to determine, from the one or more outputs, an amount of drift of a first set of metrology measurement values for the first set of substrates from a target metrology measurement value. The processing device is to further determine, from the one or more outputs, process recipe modification data identifying one or more modifications to the process recipe and, for each of the modifications, an indication of a level of confidence that a respective modification to the process recipe satisfies a drift criterion for a second set of substrates. The processing device is further to identify the respective modification with a level of confidence that satisfies a level of confidence criterion. The processing device is further to update the process recipe based on the respective modification.

In some embodiments, a method for training a machine learning model to predict a modification for a particular process recipe for a current substrate being processed at a manufacturing system is provided. The method includes generating first training data for the machine learning model. The first training data includes historical data associated with a first set of prior substrates previously processed at the manufacturing system according to a first process recipe and a first set of historical metrology measurement values associated with each of the set of prior substrates. The method further includes generating second training data for the machine learning model. The second training data includes historical data associated with a second set of prior substrates previously processed at the manufacturing system according to a second process recipe and a second set of historical metrology measurement values associated with each of the set of prior substrates. The method further includes generating third training data for the machine learning model. The third training data includes an indication of a difference between the first process recipe and the second process recipe The method further includes providing the first training data, the second training data, and the third training data to train the machine learning model to predict, for the particular process recipe for the current substrate being processed at the manufacturing system, which modification to the process recipe is to satisfy a drift criterion for a subsequent set of substrates that is to be processed after the current substrate.

In some embodiments, a non-transitory computer readable storage medium includes instructions that, when executed by a processing device, cause the processing device to provide, as input to a trained machine learning model, data associated with processing each of a first set of substrates at a manufacturing system according to a process recipe. The processing device is further to obtain one or more outputs from the trained machine learning model. The processing device is further to determine, from the one or more outputs, an amount of drift of a first set of metrology measurement values for the first set of substrates from a target metrology measurement value. The processing device is to further determine, from the one or more outputs, process recipe modification data identifying one or more modifications to the process recipe and, for each of the modifications, an indication of a level of confidence that a respective modification to the process recipe satisfies a drift criterion for a second set of substrates. The processing device is further to identify the respective modification with a level of confidence that satisfies a level of confidence criterion. The processing device is further to update the process recipe based on the respective modification.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts an illustrative computer system architecture, according to aspects of the present disclosure.

FIG. 2 is a flow chart of a method for training a machine learning model, according to aspects of the present disclosure.

FIG. 3 is a top schematic view of an example manufacturing system, according to aspects of the present disclosure.

FIG. 4 is a cross-sectional schematic side view of a substrate measurement subsystem, according to aspects of the present disclosure.

FIG. 5 illustrates spectral data collected for a substrate, according to aspects of the present disclosure.

FIG. 6 is a flow chart of a method for detecting substrate drift and predicting a modification for a particular process recipe using machine learning, according to aspects of the present disclosure.

FIG. 7 depicts a block diagram of an illustrative computer system operating in accordance with one or more aspects of the present disclosure.

### DETAILED DESCRIPTION OF EMBODIMENTS

Implementations described herein provide methods and systems detecting and correcting substrate process drift using a machine learning model. Substrate process drift refers to a drift of a quality and/or consistency of substrates processed at a manufacturing system according to a particular process recipe. Substrate process drift may be detected based on a drift of metrology measurement values for a set of substrates processed at the manufacturing system according to the process recipe from a target metrology measurement value. A metrology measurement value may include an etch rate (i.e., a rate at which a certain material deposited on the surface of the substrate is etched in a processing chamber), an etch rate uniformity (i.e., a variation of an etch rate at two or more portions of the surface of the substrate), a critical dimension (i.e., a unit of measurement for measuring a dimension of elements of a substrate, such as lines, columns, openings, spaces, etc.), critical dimension uniformity (i.e., a variation of critical dimensions across a surface of a substrate), edge to edge placement error (EPE) (i.e., a difference between the intended and resulting features included on a surface of a substrate), and so forth.

A processing device (e.g., a system controller for the manufacturing system) may receive data associated with processing a set of substrates at a manufacturing system according to a process recipe. The data may be received from sensors at various stations of a manufacturing system. For example, the processing device may receive data from sensors at a processing chamber, a transfer chamber, a load lock, a factory interface, and so forth. In some embodiments, the processing device may receive, from a substrate measurement sub-system, data associated with the substrates before or after the substrates are processed at the manufacturing system. For example, the processing device may receive spectral data associated with a profile of each substrate after each substrate is etched at a processing chamber.

The processing device may provide the data associated with processing the set of substrates and/or the data associated with the substrate before or after the substrates are processed as input the trained machine learning model and obtain one or more outputs from the machine learning model. In some embodiments, the processing device may also provide a set of metrology measurement values (e.g., an etch rate, an etch rate uniformity, a critical dimension, a critical dimension uniformity, edge to edge placement error, etc.) for the set of substrates as input to the machine learning model. For example, the processing device may determine each of the set of metrology measurement values based on spectral or non-spectral data received from the sub-substrate measurement subsystem. In another example, the processing device may receive each of the set of metrology measurement values from a metrology system coupled to the manufacturing system.

The processing device may determine, from the output of the machine learning model, an amount of drift of the set of metrology measurement values for the set of substrates from a target metrology measurement value. The processing device may also determine process recipe modification data that identifies one or more modifications to the process recipe. A modification for the process recipe may include modifying an operation of the particular process recipe or generating an instruction to terminate execution of the process recipe for a subsequent set of substrates to be processed at the manufacturing system. The process recipe modification data may also include an indication of a level of confidence that a respective modification to the process recipe satisfies a drift criterion for a second set of substrates. The processing device may determine that a modification to the process recipe satisfies a drift criterion in response to determining the respective modification is predicted to reduce an amount of substrate process drift for a set of substrates subsequently processed at the manufacturing system. The processing device may identify a respective modification having a level of confidence that satisfies a confidence criterion and update the process recipe based on the identified modification.

In some embodiments, the process recipe modification data can include an indication of one or more stations of the manufacturing system that include a defect that is the cause of the substrate process drift. In such embodiments, the processing device can transmit a notification to a user of the manufacturing system (e.g., an operator) including an indication of the one or more stations including the defect. In some embodiments, the indication can include a particular component of the one or more stations that includes the defect. The notification can be transmitted to the user of the manufacturing system with prediction for the respective modification to the process recipe, in some embodiments.

The machine learning model may be trained using historical data associated with prior substrates previously processed at the manufacturing system according to a first process recipe and a second process recipe. The machine learning model may also be trained using historical metrology measurement values associated with each of the prior substrates. For example, a processing device (e.g., the system controller) may generate first training data including historical data associated with a first set of prior substrates processed according to a first process recipe and a first set of historical metrology measurement values associated with each of the first set of prior substrates. The processing device may also generate second training data including historical data associated with a second set of prior substrates processed according to a second process recipe and a second set of historical metrology measurement values associated with each of the second set of prior substrates. The first process recipe may be similar to the second process recipe, except that at least one operation of the first process recipe is different from an operation of the second process recipe. For example, a particular operation of the first process recipe may include setting an internal temperature of a processing chamber to 100 degrees Celsius (° C.) and a corresponding operation of the second process recipe may include setting the internal temperature of the processing chamber to 110° C. The processing device may generate third training data including an indication of the difference between the first process recipe and the second process recipe. In accordance with the previous example, the third training data may indicate the difference between the first process recipe and the second process recipe corresponds to the difference of 10° C. in the temperature setting for the particular operation. The processing device may provide the first training data, the second training data, and the third training data to train the machine learning model.

Aspects of the present disclosure address the above noted deficiencies of the conventional technology by providing systems and methods for detecting and correcting substrate process drift at a manufacturing system. Substrate process drift may be detected based on a drift of metrology measurement values from a target metrology measurement value. Using the data associated with substrates processed at the manufacturing system, the machine learning model may detect when substrate process drift has occurred and predict a modification that is likely to correct the drift for substrates subsequently processed at the manufacturing system. The system controller may update a process recipe based on the predicted modification. By updating a process recipe based on the predicted modification, the amount of substrate process drift at a manufacturing system will decrease, causing a number of defects that occur within the manufacturing system to decrease, improving overall system efficiency. In addition, a substantial drift from a target metrology measurement value for a substrate may be detected and an error protocol (e.g., transmitting an error message to an operator of the manufacturing system, stopping operations at the manufacturing system, etc.) may be initiated based on the detected deviation, thus preventing unnecessary damage to the substrate and/or the manufacturing system.

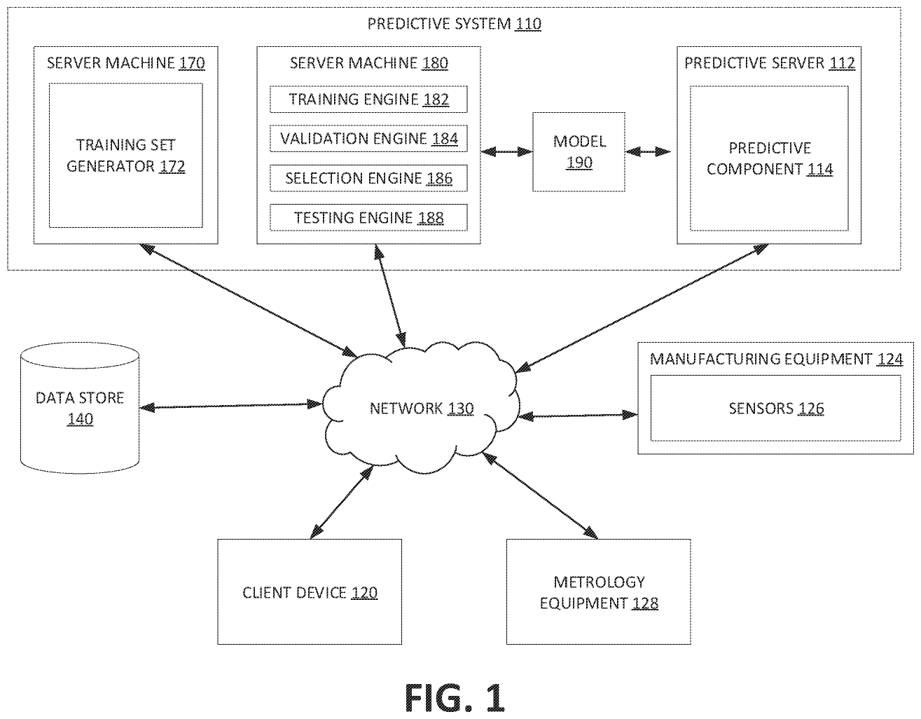

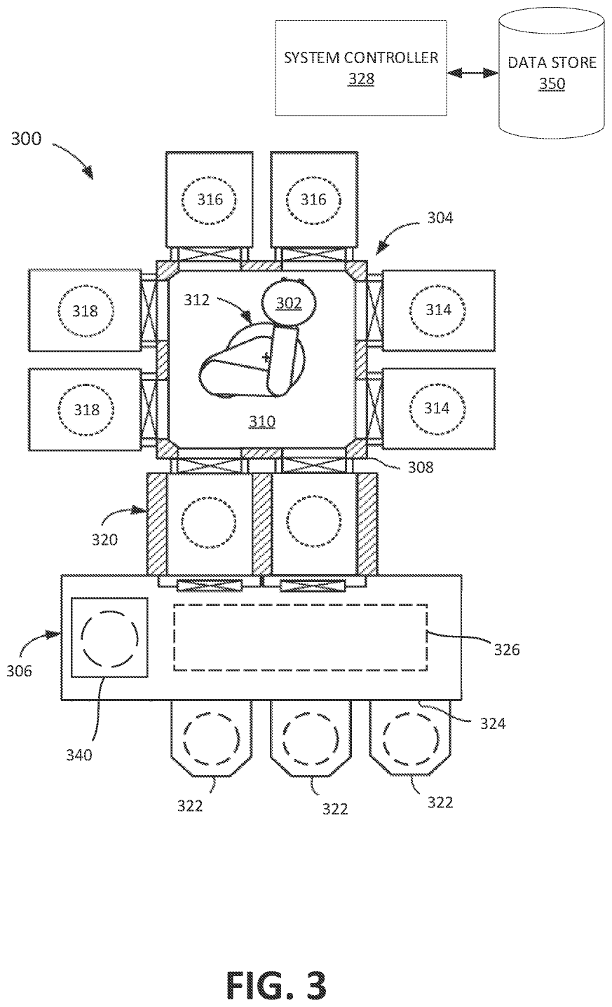

FIG. 1 depicts an illustrative computer system architecture 100, according to aspects of the present disclosure. In some embodiments, computer system architecture 100 may be included as part of a manufacturing system for processing substrates, such as manufacturing system 300 of FIG. 3. Computer system architecture 100 includes a client device 120, manufacturing equipment 124, metrology equipment 128, a predictive server 112 (e.g., to generate predictive data, to provide model adaptation, to use a knowledge base, etc.), and a data store 140. The predictive server 112 may be part of a predictive system 110. The predictive system 110 may further include server machines 170 and 180. The manufacturing equipment 124 may include sensors 125 configured to capture data for a substrate being processed at the manufacturing system. In some embodiments, the manufacturing equipment 124 and sensors 126 may be part of a sensor system that includes a sensor server (e.g., field service server (FSS) at a manufacturing facility) and sensor identifier reader (e.g., front opening unified pod (FOUP) radio frequency identification (RFID) reader for sensor system). In some embodiments, metrology equipment 128 may be part of a metrology system that includes a metrology server (e.g., a metrology database, metrology folders, etc.) and metrology identifier reader (e.g., FOUP RFID reader for metrology system).

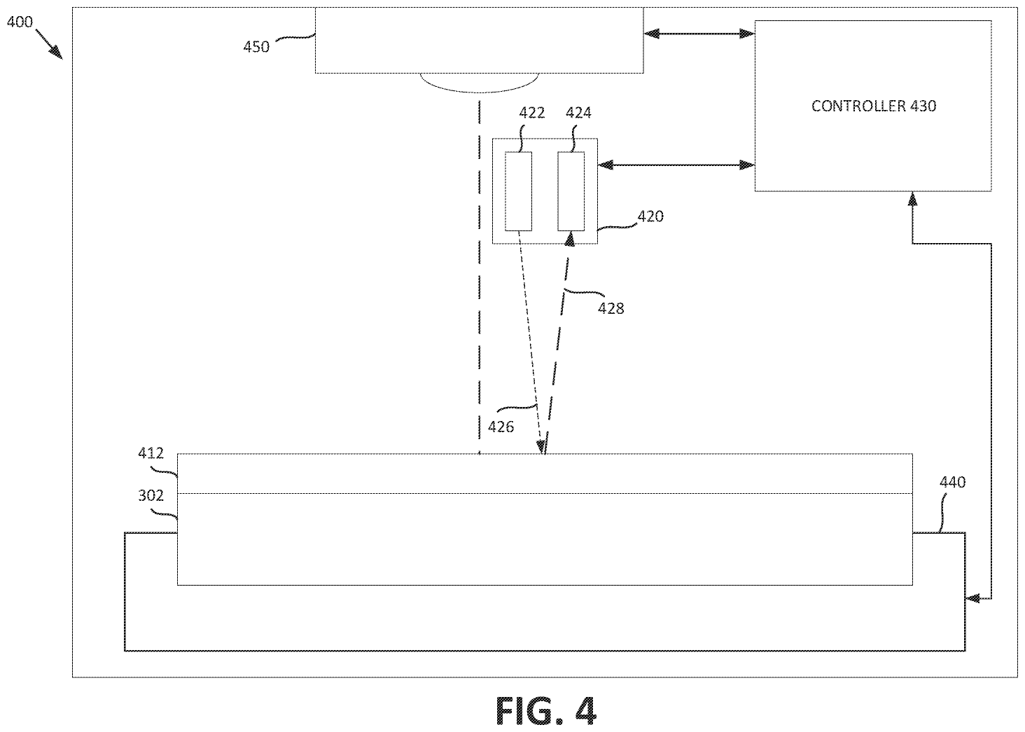

Manufacturing equipment 124 may produce products following a recipe or performing runs over a period of time. Manufacturing equipment 124 may include a substrate measurement subsystem that includes one or more sensors 126 configured to generate spectral data and/or positional data for a substrate embedded within the substrate measurement subsystem. Sensors 126 that are configured to generate spectral data (herein referred to as spectra sensing components) may include reflectometry sensors, ellipsometry sensors, thermal spectra sensors, capacitive sensors, and so forth. In some embodiments, spectra sensing components may be included within the substrate measurement subsystem or another portion of the manufacturing system. One or more sensors 126 (e.g., eddy current sensors, etc.) may also be configured to generate non-spectral data for the substrate. Further details regarding manufacturing equipment 124 and the substrate measurement subsystem are provided with respect to FIG. 3 and FIG. 4.

In some embodiments, sensors 126 may provide sensor data associated with manufacturing equipment 124. Sensor data may include a value of one or more of temperature (e.g., heater temperature), spacing (SP), pressure, high frequency radio frequency (HFRF), voltage of electrostatic chuck (ESC), electrical current, flow, power, voltage, etc. Sensor data may be associated with or indicative of manufacturing parameters such as hardware parameters, such as settings or components (e.g., size, type, etc.) of the manufacturing equipment 124, or process parameters of the manufacturing equipment 124. The sensor data may be provided while the manufacturing equipment 124 is performing manufacturing processes (e.g., equipment readings when processing products). The sensor data 142 may be different for each substrate.

Metrology equipment 128 may provide metrology data associated with substrates (e.g., wafers, etc.) processed by manufacturing equipment 124. The metrology data may include a value of one or more of film property data (e.g., wafer spatial film properties), dimensions (e.g., thickness, height, etc.), dielectric constant, dopant concentration, density, defects, etc. In some embodiments, the metrology data may further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data may be of a finished or semi-finished product. The metrology data may be different for each substrate.

The client device 120 my include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some embodiments, the metrology data may be received from the client device 120. Client device 120 may display a graphical user interface (GUI), where the GUI enables the user to provide, as input, metrology measurement values for substrates processed at the manufacturing system.

Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store data associated with processing a substrate at manufacturing equipment 124. For example, data store 140 may store data collected by sensors 126 at manufacturing equipment 124 before, during, or after a substrate process (referred to as process data). Process data can refer to historical process data (e.g., process data generated for a previous substrate processed at the manufacturing system) and/or current process data (e.g., process data generated for a current substrate processed at the manufacturing system). Data store may also store spectral data or non-spectral data associated with a portion of a substrate processed at manufacturing equipment 124. Spectral data may include historical spectral data and/or current spectral data. Current process data and/or current spectral data may be data for which predictive data is generated. In some embodiments, data store may store metrology data including historical metrology data (e.g., metrology measurement values for a prior substrate processed at the manufacturing system).

The data store 140 may also store contextual data associated with one or more substrates processed at the manufacturing system. Contextual data can include a recipe name, recipe step number, preventive maintenance indicator, operator, etc. In some embodiments, contextual data can also include an indication of a difference between two or more process recipes or process steps. For example, a first process recipe can include an operation including setting an internal temperature of a process chamber to 100° C. A second process recipe can include a corresponding operation including setting the internal temperature of the process chamber to 110° C. Contextual data can include an indication of a difference of the internal temperature of the process chamber between the first process recipe and the second process recipe.

In some embodiments, data store 140 may be configured to store data that is not accessible to a user of the manufacturing system. For example, process data, spectral data, non-spectral data, and/or positional data obtained for a substrate being processed at the manufacturing system may not be accessible to a user of the manufacturing system. In some embodiments, all data stored at data store 140 may be inaccessible by a user (e.g., an operator) of the manufacturing system. In other or similar embodiments, a portion of data stored at data store 140 may be inaccessible by the user while another portion of data stored at data store 140 may be accessible by the user. In some embodiments, one or more portions of data stored at data store 140 may be encrypted using an encryption mechanism that is unknown to the user (e.g., data is encrypted using a private encryption key). In other or similar embodiments, data store 140 may include multiple data stores where data that is inaccessible to the user is stored in one or more first data stores and data that is accessible to the user is stored in one or more second data stores.

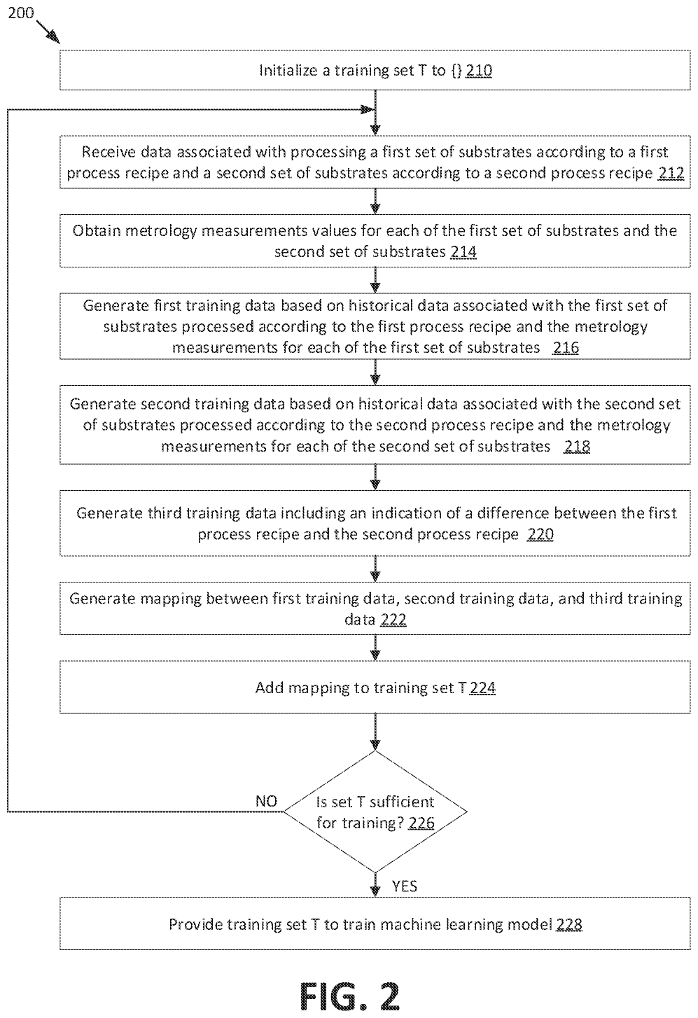

In some embodiments, predictive system 110 includes server machine 170 and server machine 180. Server machine 170 includes a training set generator 172 that is capable of generating training data sets (e.g., a set of data inputs and a set of target outputs) to train, validate, and/or test a machine learning model 190. Some operations of training set generator 172 are described in detail below with respect to FIG. 2. In some embodiments, the training set generator 172 may partition the training data into a training set, a validating set, and a testing set. In some embodiments, the predictive system 110 generates multiple sets of training data.

Server machine 180 may include a training engine 182, a validation engine 184, a selection engine 185, and/or a testing engine 186. An engine may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. Training engine 182 may be capable of training a machine learning model 190. The machine learning model 190 may refer to the model artifact that is created by the training engine 182 using the training data that includes training inputs and corresponding target outputs (correct answers for respective training inputs). The training engine 182 may find patterns in the training data that map the training input to the target output (the answer to be predicted), and provide the machine learning model 190 that captures these patterns. The machine learning model 190 may use one or more of support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network), etc.

The validation engine 184 may be capable of validating a trained machine learning model 190 using a corresponding set of features of a validation set from training set generator 172. The validation engine 184 may determine an accuracy of each of the trained machine learning models 190 based on the corresponding sets of features of the validation set. The validation engine 184 may discard a trained machine learning model 190 that has an accuracy that does not meet a threshold accuracy. In some embodiments, the selection engine 185 may be capable of selecting a trained machine learning model 190 that has an accuracy that meets a threshold accuracy. In some embodiments, the selection engine 185 may be capable of selecting the trained machine learning model 190 that has the highest accuracy of the trained machine learning models 190.

The testing engine 186 may be capable of testing a trained machine learning model 190 using a corresponding set of features of a testing set from training set generator 172. For example, a first trained machine learning model 190 that was trained using a first set of features of the training set may be tested using the first set of features of the testing set. The testing engine 186 may determine a trained machine learning model 190 that has the highest accuracy of all of the trained machine learning models based on the testing sets.

Predictive server 112 includes a predictive component 114 that is capable of providing data associated with processing each of a set of substrates at a manufacturing system according to a process recipe as input to trained machine learning model 190 and running trained machine learning model 190 on the input to obtain one or more outputs. As described in detail below with respect to FIG. 4, in some embodiments, predictive component 114 is also capable of determining process recipe modification data from the output of the trained machine learning model 190 and using the process recipe modification data to predict a modification to process recipe for a current substrate being processed at the manufacturing system that satisfies a drift criterion.

The process recipe modification data may include or indicate one or more modifications to a process recipe and, for each modification, a level of confidence that the respective modification satisfies a drift criterion. Predictive system 110 can determine that a respective modification satisfies a drift criterion in response to determining that the respective modification is predicted to cause an amount of drift of a predicted set of metrology measurement values for a subsequent set of substrates to be processed to be below a threshold amount. For example, a modification to change an internal temperature of a processing chamber by 10° C. can satisfy the drift criterion in response to predictive system 110 determining the modification is likely to cause an amount of drift of metrology measurement values for substrates that are to be processed to decrease to a threshold amount. In some embodiments, the process recipe modification data can include an indication of one or more stations at manufacturing system 100 that is causing the substrate process drift. For example, the process recipe modification data can indicate that a temperature sensor of a particular process chamber is defective. In some embodiments, predictive system 110 can transmit a notification to a user of the manufacturing system 100 (e.g., an operator) indicating the one or more stations (or one or more components of a particular station) that is causing the substrate process drift.

The client device 120, manufacturing equipment 124, sensors 126, metrology equipment 128, predictive server 112, data store 140, server machine 170, and server machine 180 may be coupled to each other via a network 130. In some embodiments, network 130 is a public network that provides client device 120 with access to predictive server 112, data store 140, and other publically available computing devices. In some embodiments, network 130 is a private network that provides client device 120 access to manufacturing equipment 124, metrology equipment 128, data store 140, and other privately available computing devices. Network 130 may include one or more wide area networks (WANs), local area networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

It should be noted that in some other implementations, the functions of server machines 170 and 180, as well as predictive server 112, may be provided by a fewer number of machines. For example, in some embodiments, server machines 170 and 180 may be integrated into a single machine, while in some other or similar embodiments, server machines 170 and 180, as well as predictive server 112, may be integrated into a single machine.

In general, functions described in one implementation as being performed by server machine 170, server machine 180, and/or predictive server 112 may also be performed on client device 120. In addition, the functionality attributed to a particular component may be performed by different or multiple components operating together.

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 is a flow chart of a method 200 for training a machine learning model, according to aspects of the present disclosure. Method 200 is performed by processing logic that may include hardware (circuitry, dedicated logic, etc.), software (such as is run on a general purpose computer system or a dedicated machine), firmware, or some combination thereof. In one implementation, method 200 may be performed by a computer system, such as computer system architecture 100 of FIG. 1. In other or similar implementations, one or more operations of method 200 may be performed by one or more other machines not depicted in the figures. In some aspects, one or more operations of method 200 may be performed by training set generator 172 of server machine 170.

For simplicity of explanation, the methods are depicted and described as a series of acts. However, acts in accordance with this disclosure may occur in various orders and/or concurrently, and with other acts not presented and described herein. Furthermore, not all illustrated acts may be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 210, processing logic initializes a training set T to an empty set (e.g., { }). At block 212, processing logic receives data associated with processing a first set of substrates according to a first process recipe and a second set of substrates according to a second process recipe. In some embodiments, the data associated with processing the first set of substrates can be received from sensors 126, as described previously. For example, the processing logic can received data from sensors at a processing chamber, a transfer chamber, a load lock, a factory interface, a substrate carrier, and so forth. In other or similar embodiments, the processing logic can also receive data from a substrate measurement subsystem, such as substrate measurement subsystem 400 described with respect to FIG. 4. The substrate measurement subsystem may be configured to capture spectral or non-spectral data associated with a substrate before or after the substrate is processed at the manufacturing system. The processing logic can receive data associated with each of the first set of substrates from the substrate measurement subsystem. The substrate measurement subsystem may be integrated with the manufacturing system (e.g., as part of a factory interface) or may not be integrated with the manufacturing system and instead may be communicatively coupled to the manufacturing system. Further details regarding the substrate measurement system are described with respect to FIGS. 3 and 4 below. It should be noted that, in additional or alternative embodiments, data associated with processing the first set of substrates may be received in some other manner, and may not be received from a portion of the manufacturing system.

At block 214, processing logic obtains metrology measurement values for each of the first set of substrates and the second set of substrates. A metrology measurement value can include at least one of an etch rate, an etch rate uniformity, a critical dimension, a critical dimension uniformity, an edge to edge placement error, etc., for a substrate processed at the manufacturing system. In some embodiments, the metrology measurement values may be received from an external metrology system coupled to the manufacturing system, as described with respect to FIG. 1. In some embodiments, the external metrology measurement system may be communicatively coupled to the manufacturing system (e.g., by network 130 of FIG. 1). In such embodiments, processing logic may receive the one or more metrology measurements for the substrate from the external metrology measurement system via the network. In other embodiments, the metrology measurements may be generated at the external metrology measurement system and provided to manufacturing system via a client device. For example, a client device connected to the manufacturing system may provide a graphical user interface (GUI) to a user of the manufacturing system (e.g., an operator). After the substrate is measured at the external metrology sub-system, the user may provide the metrology measurement value to the client device via the GUI. Responsive to receiving the provided metrology measurement value, the client device may store the metrology measurement value at a data store, such as data store 140 of the manufacturing system.

In other or similar embodiments, the processing logic can determine the metrology measurement values using a machine learning model trained to predict a metrology measurement values for a substrate processed at the manufacturing system (referred to as a metrology machine learning model). For example, spectral data may be generated for a substrate (e.g., at the substrate measurement subsystem, at a processing chamber) during or after a substrate process at the manufacturing system. The spectral data may be provided to the trained metrology machine learning model as an input. In some embodiments, positional data may also be generated for the substrate (e.g., at the substrate measurement subsystem), where the positional data is associated with the spectral data. In such embodiments, the positional data may be provided to the trained metrology machine learning model with the spectral data as another input. The trained metrology machine learning model can produce one or more outputs including a metrology measurement value for a prior substrate processed at the manufacturing system and a level of confidence that the current substrate being processed at the manufacturing system is associated with the metrology measurement for the prior substrate. The processing logic may determine a metrology measurement value corresponds with the current substrate in response to determining the level of confidence for the current substrate satisfies a level of confidence criterion.

In some embodiments, the processing logic can receive each metrology measurement value for each of the first set of substrates and/or the second set of substrates from the metrology system coupled to the manufacturing system. In other or similar embodiments, the processing logic can determine each metrology measurement value for each of the first set of substrates and/or the second set of substrates using the trained metrology machine learning model. In other or similar embodiments, the processing logic can receive a metrology measurement value for one or more substrates of the first set of substrates and/or the second set of substrates from the metrology system and determine a metrology measurement value using the trained metrology machine learning model.

At block 216, processing logic generates first training data based on historical data associated with the first set of substrates processed according to the first process recipe and the metrology measurement for each of the first set of substrates. At block 218, processing logic generates second training data based on historical data associated with the first set of substrates processed according to the first process recipe and the metrology measurement for each of the first set of substrates. At block 220, processing logic generates third training data including an indication of a difference between the first process recipe and the second process recipe. For example, the first process recipe can include an operation including setting an internal temperature of a process chamber to 100° C. The second process recipe can include a corresponding operation including setting the internal temperature of the process chamber to 110° C. The third training data can include an indication of a difference of the internal temperature of the process chamber between the first process recipe and the second process recipe.

At block 222, processing logic generates a mapping between the first training data, the second training data, and the third training data. The mapping refers to the first training data that includes or is based on data for the first set of substrates processed according to the first process recipe, the second training data that includes or is based on data for the second set of substrates processed according to the second process recipe, and the third training data including the indication of a difference between the first process recipe and the second process recipe, and where the first training data and the second training data is associated with (or mapped to) the third training data. At block 224, processing logic adds the mapping to the training set T.

At block 226, processing logic determines whether the training set, T, includes a sufficient amount of training data to train a machine learning model. It should be noted that in some implementations, the sufficiency of training set T may be determined based simply on the number of mappings in the training set, while in some other implementations, the sufficiency of training set T may be determined based on one or more other criteria (e.g., a measure of diversity of the training examples, etc.) in addition to, or instead of, the number of input/output mappings. Responsive to determining the training set does not include a sufficient amount of training data to train the machine learning model, method 200 returns to block 212. Responsive to determining the training set, T, includes a sufficient amount of training data to train the machine learning model, method 200 continues to block 228.

At block 228, processing logic provides the training set T to train the machine learning model. In one implementation, the training set T is provided to training engine 182 of server machine 180 to perform the training. In the case of a neural network, for example, input values of a given input/output mapping (e.g., spectral data for a previous substrate) are input to the neural network, and output values of the input/output mapping are stored in the output nodes of the neural network. The connection weights in the neural network are then adjusted in accordance with a learning algorithm (e.g., backpropagation, etc.), and the procedure is repeated for the other input/output mappings in the training set T. After block 228, machine learning model 190 may be used to predict, for a particular process recipe for a current substrate being processed at the manufacturing system, which modification to the process recipe is to satisfy a drift criterion for a subsequent set of substrates that is to be processed after the current substrate.

FIG. 3 is a top schematic view of an example manufacturing system 300, according to aspects of the present disclosure. Manufacturing system 300 may perform one or more processes on a substrate 302. Substrate 302 may be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 300 may include a process tool 304 and a factory interface 306 coupled to process tool 304. Process tool 304 may include a housing 308 having a transfer chamber 310 therein. Transfer chamber 310 may include one or more processing chambers (also referred to as process chambers) 314, 316, 318 disposed therearound and coupled thereto. Processing chambers 314, 316, 318 may be coupled to transfer chamber 310 through respective ports, such as slit valves or the like. Transfer chamber 310 may also include a transfer chamber robot 312 configured to transfer substrate 302 between process chambers 314, 316, 318, load lock 320, etc. Transfer chamber robot 312 may include one or multiple arms where each arm includes one or more end effectors at the end of each arm. The end effector may be configured to handle particular objects, such as wafers.

Processing chambers 314, 316, 318 may be adapted to carry out any number of processes on substrates 302. A same or different substrate process may take place in each processing chamber 314, 316, 318. A substrate process may include atomic layer deposition (ALD), physical vapor deposition (PVD), chemical vapor deposition (CVD), etching, annealing, curing, pre-cleaning, metal or metal oxide removal, or the like. In some embodiments, a substrate process may include a combination of two or more of atomic layer deposition (ALD), physical vapor deposition (PVD), chemical vapor deposition (CVD), etching, annealing, curing, pre-cleaning, metal or metal oxide removal, or the like. Other processes may be carried out on substrates therein. Processing chambers 314, 316, 318 may each include one or more sensors configured to capture data for substrate 302 before, after, or during a substrate process. For example, the one or more sensors may be configured to capture spectral data and/or non-spectral data for a portion of substrate 302 during a substrate process. In other or similar embodiments, the one or more sensors may be configured to capture data associated with the environment within processing chamber 314, 316, 318 before, after, or during the substrate process. For example, the one or more sensors may be configured to capture data associated with a temperature, a pressure, a gas concentration, etc. of the environment within processing chamber 314, 316, 318 during the substrate process.

A load lock 320 may also be coupled to housing 308 and transfer chamber 310. Load lock 320 may be configured to interface with, and be coupled to, transfer chamber 310 on one side and factory interface 306. Load lock 320 may have an environmentally-controlled atmosphere that may be changed from a vacuum environment (wherein substrates may be transferred to and from transfer chamber 310) to an inert-gas environment at or near atmospheric-pressure (wherein substrates may be transferred to and from factory interface 306) in some embodiments. Load lock 320 may include one or more sensors to capture data associated with substrate 302 before, after, or during a substrate process at processing chambers 314, 316, 318. For example, load lock 320 may include a vibration sensor (e.g., a piezoelectric sensor) configured to detect and monitor an amount of vibration occurring within load lock 320 during a substrate process at processing chambers 314, 316, 318. In another example, load lock 320 may include a temperature sensor (e.g., an infrared camera) to detect and monitor a temperature of load lock 320 during a substrate process. It should be noted that, although embodiments of the present disclosure describe sensors such as a vibration sensor or a temperature sensor at load lock 320 to monitor a state of load lock 320 during a substrate process, any type of sensor can be used at any station of manufacturing system 100 to monitor the state and/or health of the station during a substrate process.

Factory interface 306 may be any suitable enclosure, such as, e.g., an Equipment Front End Module (EFEM). Factory interface 306 may be configured to receive substrates 302 from substrate carriers 322 (e.g., Front Opening Unified Pods (FOUPs)) docked at various load ports 324 of factory interface 306. A factory interface robot 326 (shown dotted) may be configured to transfer substrates 302 between carriers (also referred to as containers) 322 and load lock 320. Carriers 322 may be a substrate storage carrier or a replacement part storage carrier. Factory interface 306 and/or carriers 322 may include one or more sensors (e.g., a vibration sensor, a temperature sensor, etc.) to capture data associated with substrate 302 before, after, or during a substrate process at processing chambers 314, 316, 318, in accordance with previously described embodiments.

Manufacturing system 300 may also be connected to a client device (not shown) that is configured to provide information regarding manufacturing system 300 to a user (e.g., an operator). In some embodiments, the client device may provide information to a user of manufacturing system 300 via one or more graphical user interfaces (GUIs). For example, the client device may provide information regarding one or more modifications to be made to a process recipe for a substrate 302 via a GUI.

Manufacturing system 300 may also include a system controller 328. System controller 328 may be and/or include a computing device such as a personal computer, a server computer, a programmable logic controller (PLC), a microcontroller, and so on. System controller 328 may include one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. System controller 328 may include a data storage device (e.g., one or more disk drives and/or solid state drives), a main memory, a static memory, a network interface, and/or other components. System controller 328 may execute instructions to perform any one or more of the methodologies and/or embodiments described herein. In some embodiments, system controller 328 may execute instructions to perform one or more operations at manufacturing system 300 in accordance with a process recipe. The instructions may be stored on a computer readable storage medium, which may include the main memory, static memory, secondary storage and/or processing device (during execution of the instructions).

System controller 328 may receive data from sensors included on or within various portions of manufacturing system 300 (e.g., processing chambers 314, 316, 318, transfer chamber 310, load lock 320, etc.). In some embodiments, data received by the system controller 328 may include spectral data and/or non-spectral data for a portion of substrate 302. In other or similar embodiments, data received by the system controller 328 may include data associated with processing substrate 302 at processing chamber 314, 316, 318, as described previously. For purposes of the present description, system controller 328 is described as receiving data from sensors included within processing chambers 314, 316, 318. However, system controller 328 may receive data from any portion of manufacturing system 300 and may use data received from the portion in accordance with embodiments described herein. In an illustrative example, system controller 328 may receive data from one or more sensors for processing chamber 314, 316, 318 before, after, or during a substrate process at the processing chamber 314, 316, 318. Data received from sensors of the various portions of manufacturing system 300 may be stored in a data store 350. Data store 350 may be included as a component within system controller 328 or may be a separate component from system controller 328. In some embodiments, data store 350 may be data store 140 described with respect to FIG. 1.

Manufacturing system 300 may further include a substrate measurement subsystem 340. Substrate measurement subsystem 340 may obtain spectra measurements for one or more portions of a substrate 302 before or after the substrate 302 is processed at manufacturing system 300. In some embodiments, substrate measurement subsystem 340 may obtain spectra measurements for one or more portions of substrate 302 in response to receiving a request for the spectra measurements from system controller 328. Substrate measurement subsystem 340 may be integrated within a portion of manufacturing system 300. In some embodiments, substrate measurement subsystem 340 may be integrated within factory interface 306. In other or similar embodiments, substrate measurement subsystem 340 may not be integrated with any portion of manufacturing system 300 and instead may be a stand-alone component. In such embodiments, a substrate 302 measured at substrate measurement subsystem 340 may be transferred to and from a portion of manufacturing system 300 prior to or after the substrate 302 is processed at manufacturing system 300.

Substrate measurement subsystem 340 may obtain spectra measurements for a portion of substrate 302 by generating spectral data and/or spectral for the portion of substrate 302. In some embodiments, substrate measurement subsystem 340 is configured to generate spectral data, non-spectral data, positional data, and other substrate property data for substrate 302 (e.g., a thickness of substrate 302, a width of substrate 302, etc.). After generating data for substrate 302, substrate measurement subsystem 340 may transmit the generated data to system controller 328. Responsive to receiving data from substrate measurement subsystem 340, system controller 328 may store the data at data store 350.

FIG. 4 is a cross-sectional schematic side view of a substrate measurement subsystem 400, according to aspects of the present disclosure. Substrate measurement subsystem 400 may be configured to obtain measurements for one or more portions of a substrate, such as substrate 302 of FIG. 3, prior to or after processing of substrate 302 at a processing chamber. Substrate measurement subsystem 400 may obtain measurements for a portion of substrate 302 by generating data (e.g., spectral data, non-spectral data, etc.) associated with the portion of substrate 302. In some embodiments, substrate measurement subsystem 400 may be configured to generate spectral data, non-spectral data, positional data, and/or other property data associated with substrate 302. Substrate measurement subsystem 400 may include a controller 430 configured to execute one or more instructions for generating data associated with a portion of substrate 302.

Substrate measurement subsystem 400 may detect that substrate 302 has been transferred to substrate measurement subsystem 400. Responsive to detecting that substrate 302 has been transferred to substrate measurement subsystem 400, substrate measurement subsystem 400 may determine a position and/or an orientation of substrate 302. The position and/or orientation of substrate 302 may be determined based on an identification of a reference location of substrate 302. A reference location may be a portion of substrate 302 that includes an identifying feature that is associated with a specific portion of substrate 302. Controller 328 may determine an identifying feature associated with a specific portion of substrate 302 based on determined identifying information for substrate 302.

Controller 430 may identify the reference location for substrate 302 using one or more camera components 450 configured to capture image data for substrate 302. Camera components 450 may generate image data for with one or more portions of the substrate 302 and transmit the image data to controller 430. Controller 430 may analyze the image data to identify an identifying feature associated with a reference location for substrate 302. Controller 430 may further determine a position and/or orientation of substrate 302 as depicted in the image data based on the identified identifying feature of substrate 302. Controller 430 may determine a position and/or orientation of substrate 302 based on the identified identifying feature of substrate 302 and the determined position and/or orientation of substrate 302 as depicted in the image data. Responsive to determining the position and/or orientation of substrate 302, controller 430 may generate positional data associated with one or more portions of substrate 302. In some embodiments, the positional data may include one or more coordinates (e.g., Cartesian coordinates, polar coordinates, etc.) each associated with a portion of substrate 302, where each coordinate is determined based on a distance from the reference location for substrate 302

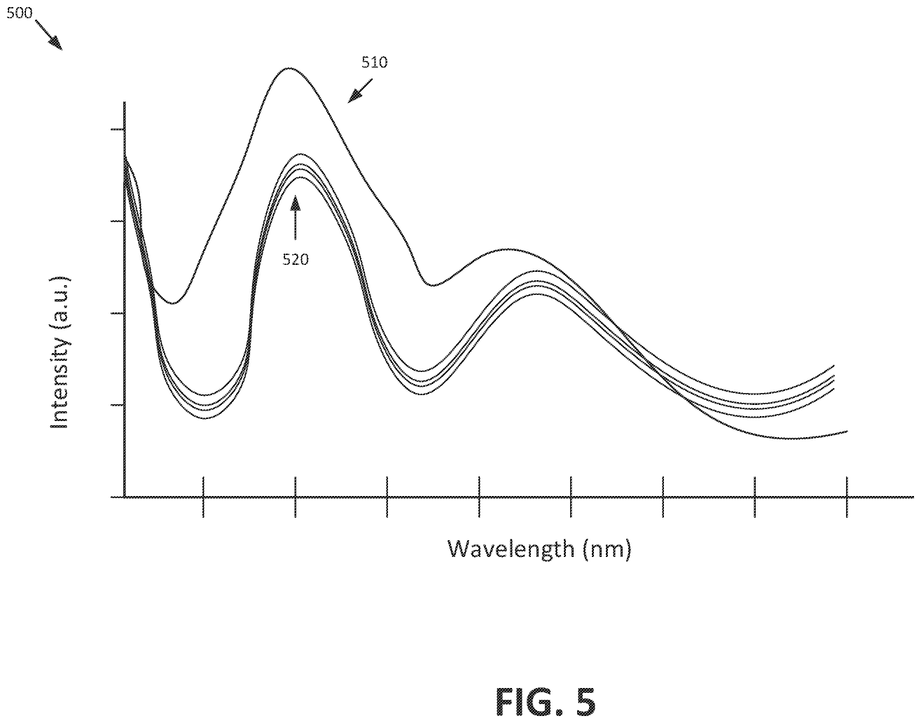

Substrate measurement subsystem 400 may include one or more measurement components for measuring substrate 302. In some embodiments, substrate measurement subsystem 400 may include one or more spectra sensing components 420 configured to generate spectral data for one or more portions of substrate 302. As discussed previously, spectral data may correspond to an intensity (i.e., a strength or amount of energy) of a detected wave of energy for each wavelength of the detected wave. Further details regarding the collected spectral data is provided with respect to FIG. 5.

A spectra sensing component 420 may be configured to detect waves of energy reflected from a portion of substrate 302 and generate spectral data associated with the detected waves. Spectra sensing component 420 may include a wave generator 422 and a reflected wave receiver 424. In some embodiments, wave generator 422 may be a light wave generator configured to generate a beam of light towards a portion of substrate 302. In such embodiments, reflected wave receiver 424 may be configured to receive a reflected light beam from the portion of substrate 302. Wave generator 422 may be configured to generate an energy stream 426 (e.g., a light beam) and transmit energy stream 426 to a portion of substrate 302. A reflected energy wave 428 may be reflected from the portion of substrate 302 and received by reflected wave receiver 424. Although FIG. 3A illustrates a single energy wave reflected off the surface of substrate 302, multiple energy waves may be reflected off the surface of substrate 302 and received by reflected wave receiver 424.

Responsive to reflected wave receiver 424 receiving reflected energy wave 428 from the portion of substrate 302, spectra sensing component 420 may measure a wavelength of each wave included in reflected energy wave 428. Spectra sensing component 420 may further measure an intensity of each measured wavelength. Responsive to measuring each wavelength and each wavelength intensity, spectra sensing component 420 may generate spectral data for the portion of substrate 302. Spectra sensing component 420 may transmit the generated spectral data to controller 430. Controller 430 may, responsive to receiving the generated spectral data, generate a mapping between the received spectral data and positional data for the measured portion of substrate 302.

Substrate measurement subsystem 400 may be configured to generate a specific type of spectral data based on a type of measurement to be obtained at substrate measurement subsystem 400. In some embodiments, spectra sensing component 420 may be a first spectra sensing component that is configured to generate one type of spectral data. For example, spectra sensing component 420 may be configured to generate reflectometry spectral data, ellipsometry spectral data, hyperspectral imaging data, chemical imaging data, thermal spectral data, or conductive spectral data. In such embodiments, the first spectra sensing component may be removed from substrate measurement subsystem 400 and replaced with a second spectra sensing component configured to generate a different type of spectral data (e.g., reflectometry spectral data, ellipsometry spectral data, hyperspectral imaging data, chemical imaging data, eddy current spectral data, thermal spectral data, or conductive spectral data).

In some embodiments, one or more measurement components, such as spectra sensing component 420, may be stationary components within substrate measurement subsystem 400. In such embodiments, substrate measurement subsystem 400 may include one or more positional components 440 configured to modify a position and/or an orientation of substrate 302 with respect to spectra sensing component 420. In some embodiments, positional components 440 may be configured to translate substrate 302 along a first axis and or a second axis, relative to spectra sensing component 420. In other or similar embodiments, positional components 440 may be configured to rotate substrate 302 around a third axis relative to spectra sensing component 420.

As spectra sensing component 420 generates spectral data for one or more portions of substrate 302, positional components 440 may modify the position and/or orientation of substrate 302 in accordance with the one or more determined portions to be measured for substrate 302. For example, prior to spectra sensing component 420 generating spectral data for substrate 302, positional components 440 may position substrate 302 at Cartesian coordinate (0,0) and spectra sensing component 420 may generate first spectral data for substrate 302 at Cartesian coordinate (0,0). Responsive to spectra sensing component 420 generating first spectral data for substrate 302 at Cartesian coordinate (0,0), positioning components 440 may translate substrate 302 along a first axis so that spectra sensing component 420 is configured to generate second spectral data for substrate 302 at Cartesian coordinate (0,1). Responsive to spectra sensing component 420 generating second spectral data for substrate 302 at Cartesian coordinate (0,1), controller 430 may rotate substrate 302 along a second axis so that spectra sensing component 420 is configured to generate third spectral data for substrate 302 at Cartesian coordinate (1,1). This process may occur multiple times until spectral data is generated for each determined portion of substrate 302.

In some embodiments, one or more layers 412 of material may be included on a surface of substrate 302. The one or more layers 412 may include etch material, photoresist material, mask material, deposited material, etc. In some embodiments, the one or more layers 412 may include an etch material to be etched according to an etch processed performed at a processing chamber. In such embodiments, spectral data may be collected for one or more portions of the un-etched etch material of the layer 412 deposited on substrate 302, in accordance with previously disclosed embodiments. In other or similar embodiments, the one or more layers 412 may include an etch material that has already been etched according an etch process at the processing chamber. In such embodiments, one or more structural features (e.g., lines, columns, openings, etc.) may be etched into the one or more layers 412 of substrate 302. In such embodiments, spectral data may be collected for one or more structural features etched into the one or more layers 412 of substrate 302.

Responsive to receiving at least one of the spectral data, the positional data, or the property data for the substrate 302, controller 430 may transmit the received data to system controller 328 for processing and analysis, in accordance with embodiment described herein.

FIG. 5 illustrates spectral data 500 collected for a substrate, according to aspects of the present disclosure. Spectral data may be generated from reflected energy received by the substrate measurement subsystem 400 of FIG. 4 or a sensor of a processing chamber, such as processing chamber 314, 316, 318 of FIG. 3, according to aspects of the present disclosure. As illustrated, multiple wave lengths may be included in reflected energy waves received by substrate measurement subsystem 400. Each reflected energy wave may be associated with a different portion of substrate 302. In some embodiments, an intensity may be measured for each reflected energy wave received by substrate measurement subsystem 400. As seen in FIG. 5, each intensity may be measured for each wavelength of reflected energy waves received by substrate measurement subsystem 400. The association between each intensity and each wavelength may be the basis for the formation of spectral data 500. In some embodiments, one or more wavelengths may be associated with an intensity value that is outside of an expected range of intensity values. For example, line 510 may be associated with an intensity value that is outside of the expected range of intensity values, as illustrated by lines 520. In such embodiments, the intensity value that is outside of the expected range of intensity values may be an indication that a defect exists at a portion of substrate 302.

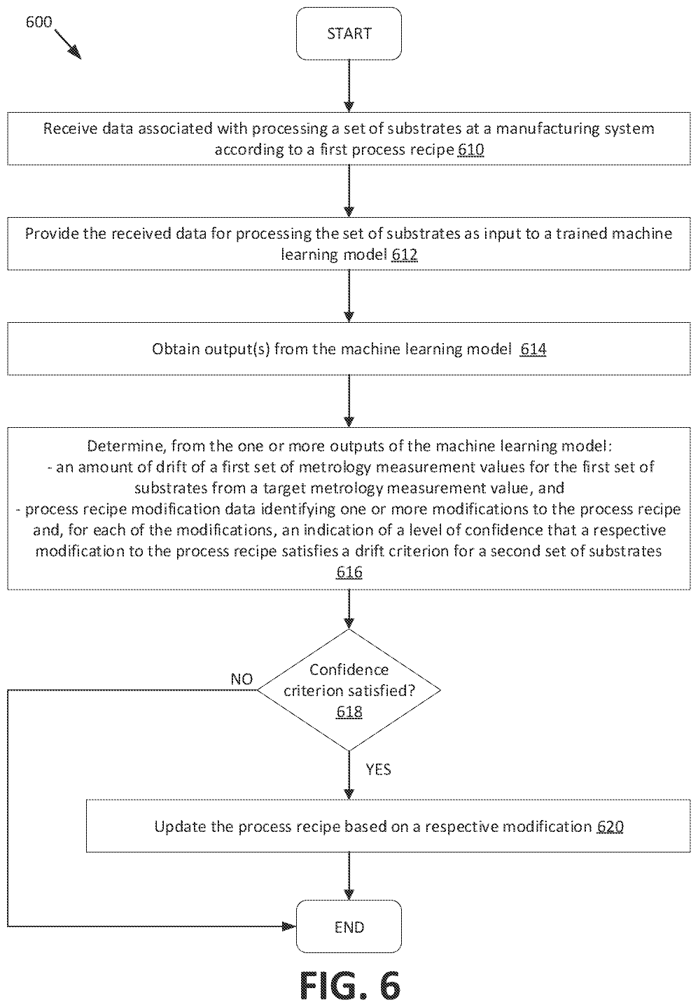

FIG. 6 is a flow chart of a method 600 for detecting substrate drift and predicting a modification for a particular process recipe using machine learning, according to aspects of the present disclosure. Method 600 is performed by processing logic that may include hardware (circuitry, dedicated logic, etc.), software (such as is run on a general purpose computer system or a dedicated machine), firmware, or some combination thereof. In some embodiments, method 600 may be performed using predictive server 112 and trained machine learning model 190 of FIG. 1. In other or similar embodiments, one or more blocks of FIG. 6 may be performed by one or more other machines not depicted in FIG. 1.

At block 610, processing logic receives data associated with processing a set of substrates at a manufacturing system according to a first process recipe. In some embodiments, processing logic may receive data associated with processing the set of substrates from sensors 126, as described previously. For example, the processing logic can received data from sensors at a processing chamber, a transfer chamber, a load lock, a factory interface, a substrate carrier, and so forth. In other or similar embodiments, the processing logic can also receive data from a substrate measurement subsystem.

At block 612, processing logic provides the received data for processing the set of substrates as input to a trained machine learning model. In some embodiments, the processing logic can obtain a set of metrology measurement values for each of the set of substrates, in accordance with previously described embodiments. For example, the processing logic can receive the set of metrology measurement values from an external metrology system or a client device connected to the manufacturing system. In another example, the processing logic can determine each of the set of metrology measurement values using a trained metrology machine learning model.

At block 614, processing logic obtains outputs from the machine learning model. At block 616, processing logic determines, from the one or more outputs, an amount of drift of a first set of metrology measurement values for the first set of substrates from a target metrology measurement value. The processing logic also determines, from the one or more outputs, process recipe modification data identifying one or more modifications to the process recipe and, for each of the modifications, an indication of a level of confidence that a respective modification satisfies a drift criterion for a second set of substrates. A modification for the process recipe may include modifying an operation of the particular process recipe or generating an instruction to terminate execution of the process recipe for a subsequent set of substrates to be processed at the manufacturing system. In some embodiments, the processing logic can also determine, from the one or more outputs, an identifier of one or more components at the manufacturing system that is causing the drift. In such embodiments, a modification for the process recipe may include generating an instruction for the system controller to monitor the state of the component during subsequent processes to determine whether the component is to be replaced.

At block 618, processing logic determines whether a level of confidence criterion for each of the one or more modifications is satisfied. In response to determining the level of confidence criterion is not satisfied for any of the one or more modifications, method 600 ends. The processing logic may determine that a modification to the process recipe satisfies a drift criterion in response to determining the respective modification is predicted to reduce an amount of substrate process drift for a set of substrates subsequently processed at the manufacturing system. In response to determining the level of confidence criterion is satisfied for at least one of the one or more modifications, the processing logic identifies the modification that satisfies the level of confidence criterion.

At block 620, processing logic updates the process recipe based on the identified modification. For example, the processing logic can one or more operations of the process recipe for the subsequent substrates to be processed at the manufacturing system. In another example, the processing logic can generate an instruction to terminate execution of the process recipe for the subsequent set of substrates. In some embodiments, the processing logic can generate a notification to an operator of the manufacturing system indicating the identified modification. For example, the notification may be provided via a GUI display via a client device. The notification may include the identified modification along with one or more GUI elements that enable the operator to accept or reject the modification. In other or similar embodiments, the notification may provide multiple alternative modifications to the process recipe along with one or more GUI elements that enable the operator to select a prediction over other alternative modifications. In other or similar embodiments, the processing logic may not provide a notification to an operator of the manufacturing system and instead may modify the process recipe based on the identified modification.

In some embodiments, the modification to the operation can be predicted as a result of a defect occurring at one or more stations of the manufacturing system. In such embodiments, the processing logic can provide a notification to an operator of the manufacturing system indicating the station that includes the defect and, in some instances, a particular component at the station that is causing the defect. The notification can be provided with the notification of the modification to the process recipe or separately from the notification of the modification.

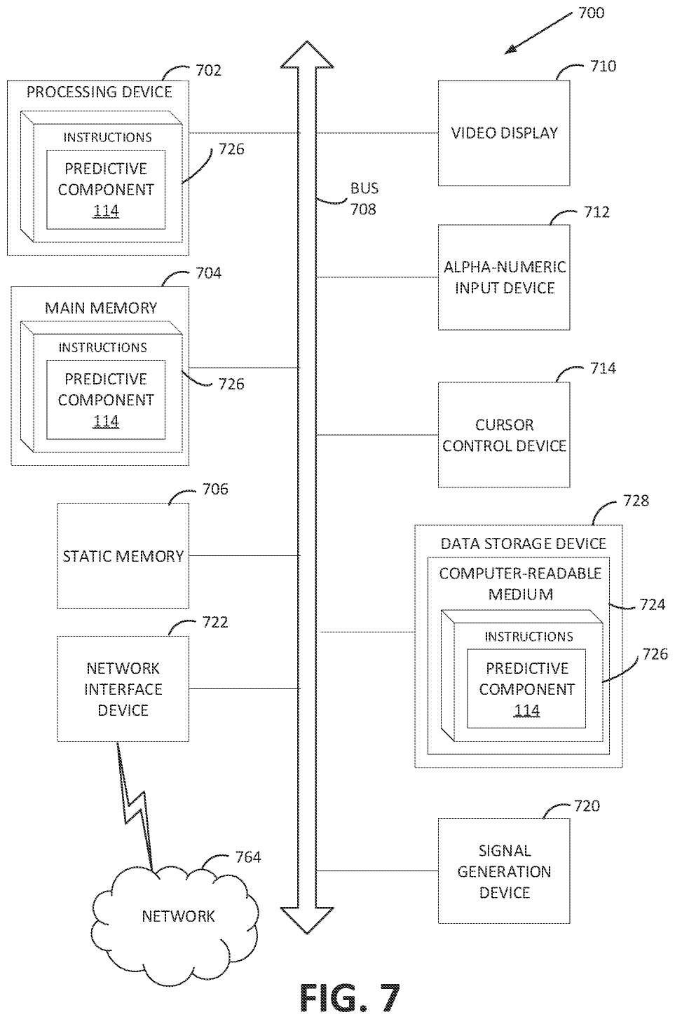

FIG. 7 depicts a block diagram of an illustrative computer system 700 operating in accordance with one or more aspects of the present disclosure. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 1100 may correspond to system controller 328 of FIG. 3 or another processing device of manufacturing system 100.

The example computing device 700 includes a processing device 702, a main memory 704 (e.g., read-only memory (ROM), flash memory, dynamic random access memory (DRAM) such as synchronous DRAM (SDRAM), etc.), a static memory 706 (e.g., flash memory, static random access memory (SRAM), etc.), and a secondary memory (e.g., a data storage device 728), which communicate with each other via a bus 708.

Processing device 702 may represent one or more general-purpose processors such as a microprocessor, central processing unit, or the like. More particularly, the processing device 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. Processing device 702 may also be or include a system on a chip (SoC), programmable logic controller (PLC), or other type of processing device. Processing device 702 is configured to execute the processing logic for performing operations and steps discussed herein.

The computing device 700 may further include a network interface device 722 for communicating with a network 764. The computing device 700 also may include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 720 (e.g., a speaker).

The data storage device 728 may include a machine-readable storage medium (or more specifically a non-transitory computer-readable storage medium) 724 on which is stored one or more sets of instructions 726 embodying any one or more of the methodologies or functions described herein. Wherein a non-transitory storage medium refers to a storage medium other than a carrier wave. The instructions 726 may also reside, completely or at least partially, within the main memory 704 and/or within the processing device 702 during execution thereof by the computer device 700, the main memory 704 and the processing device 702 also constituting computer-readable storage media.

The computer-readable storage medium 724 may also be used to store model 190 and data used to train model 190. The computer readable storage medium 724 may also store a software library containing methods that call model 190. While the computer-readable storage medium 724 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a memory to store a trained machine learning model; and
a processing device coupled to the memory, the processing device to:
provide, as input to a trained machine learning model, data associated with processing each of a first set of substrates at a manufacturing system according to a process recipe;
obtain one or more outputs from the trained machine learning model;
determine, from the one or more outputs:
an amount of drift of a first set of metrology measurement values for the first set of substrates from a target metrology measurement value, and
process recipe modification data identifying one or more modifications to the process recipe and, for each of the modifications, an indication of a level of confidence that a respective modification to the process recipe satisfies a drift criterion for a second set of substrates; and
responsive to identifying the respective modification with a level of confidence that satisfies a level of confidence criterion, update the process recipe based on the respective modification.

2. The system of claim 1, wherein the processing device is further to:
receive, from a substrate measurement subsystem, a first set of measurements for each of the first set of substrates, the first set of measurements comprising at least one of spectral data or non-spectral data associated with a profile of a respective substrate of the first set of substrates, wherein the data associated with processing each of the first set of substrates comprises the at least one of the spectral data or the non-spectral data of the first set of measurements.

3. The system of claim 2, wherein the processing device is further to:
receive a second set of measurements for each of the first set of substrates, the second set of measurements received from one or more sensors of at least one of a processing chamber, a transfer chamber, a load lock, a factory interface, or a substrate storage container of the manufacturing system.

4. The system of claim 1, wherein the processing device is further to:
provide, as additional input to the trained machine learning model, the set of first metrology measurement values for the first set of substrates.

5. The system of claim 1, wherein a respective modification to the process recipe satisfies the drift criterion for the second set of substrates in response to a determination that the respective modification is predicted to cause an amount of drift of a predicted set of metrology measurement values for the second set of substrates to be below a threshold amount.

6. The system of claim 1, wherein updating the process recipe based on the respective modification comprises at least one of modifying an operation of the process recipe or generating an instruction to terminate execution of the process recipe for the second set of substrates.

7. The system of claim 6, wherein to update the process recipe based on the respective modification, the processing device is further to:
transmit, to a client device connected to the manufacturing system, a request to modify the process recipe for the second set of substrates; and
receive, from the client device, an instruction to modify the process recipe for the second set of substrates, wherein the process recipe is updated in accordance with the received instruction.

8. The system of claim 1, wherein the level of confidence of the respective modification satisfies the level of confidence criterion responsive to a determination that the level of confidence exceeds a threshold level of confidence value.

9. A method for training a machine learning model to predict a modification for a particular process recipe for a current substrate being processed at a manufacturing system, the method comprising:
generating first training data for the machine learning model, wherein the first training data comprise historical data associated with a first set of prior substrates previously processed at the manufacturing system according to a first process recipe and a first set of historical metrology measurement values associated with each of the set of prior substrates;
generating second training data for the machine learning model, wherein the second training data comprise historical data associated with a second set of prior substrates previously processed at the manufacturing system according to a second process recipe and a second set of historical metrology measurement values associated with each of the set of prior substrates;
generating third training data for the machine learning model, wherein the third training data comprises an indication of a difference between the first process recipe and the second process recipe; and
providing the first training data, the second training data, and the third training data to train the machine learning model to predict, for the particular process recipe for the current substrate being processed at the manufacturing system, which modification to the process recipe is to satisfy a drift criterion for a subsequent set of substrates that is to be processed after the current substrate.

10. The method of claim 9, wherein generating the first training data comprises:
determining, for each of the prior substrates of the first set of prior substrates, a respective historical measurement value based on at least one of historical spectral data or historical non-spectral data generated for one or more portions of the prior substrate.

11. The method of claim 10, further comprising receiving, from a substrate measurement subsystem of the manufacturing system, a first set of measurements for a portion of a first prior substrate of the first set of prior substrates, the first set of measurements comprising at least one of respective historical spectral data or respective historical non-spectral data generated for the portion of the first prior substrate.

12. The method of claim 9, wherein generating the first training data comprises:
receiving, from a metrology system communicatively coupled to the manufacturing system, the first set of historical measurement values associated with each of the first set of prior substrates.

13. The method of claim 9, wherein generating the first training data comprises determining, for each of the prior substrates of the first set of prior substrates, a respective historical measurement value based on at least one of historical spectral data or historical non-spectral data for one or more portions of the respective prior substrate, and wherein generating the second training data comprises receiving the second set of historical measurement values associated with each of the second set of prior substrates from at least one of a client device connected to the manufacturing system or a metrology measurement tool connected to the manufacturing system.

14. The method of claim 9, wherein generating the first training data comprises:
receiving a set of measurements from one or more sensors of at least one of a processing chamber, a transfer chamber, a load lock, a factory interface, or a substrate storage container of the manufacturing system, the set of measurements generated during a performance of the first process recipe for each of the first set of prior substrates, wherein the historical data associated with the first set of prior substrates comprises the received set of measurements.

15. A non-transitory computer readable storage medium comprising instructions that, when executed by a processing device, cause the processing device to:
provide, as input to a trained machine learning model, data associated with processing each of a first set of substrates at a manufacturing system according to a process recipe;
obtain one or more outputs from the trained machine learning model;
determine, from the one or more outputs:
an amount of drift of a first set of metrology measurement values for the first set of substrates from a target metrology measurement value, and
process recipe modification data identifying one or more modifications to the process recipe and, for each of the modifications, an indication of a level of confidence that a respective modification to the process recipe satisfies a drift criterion for a second set of substrates; and
responsive to identifying the respective modification with a level of confidence that satisfies a level of confidence criterion, update the process recipe based on the respective modification.

16. The non-transitory computer readable storage medium of claim 15, wherein the processing device is further to:
receive, from a substrate measurement subsystem, a first set of measurements for a first substrate of the first set of substrates, the first set of measurements comprising at least one of spectral data or non-spectral data associated with a profile of each of the first substrate, wherein the data associated with processing each of the first set of substrates comprises the at least one of the spectral data or non-spectral data of the set of measurements

17. The non-transitory computer readable storage medium of claim 16, wherein the processing device is further to:
receiving a second set of measurements for the first substrate from one or more sensors of at least one of a processing chamber, a transfer chamber, a load lock, a factory interface, or a substrate storage container of the manufacturing system.

18. The non-transitory computer readable storage medium of claim 15, wherein the processing device is further to:
provide, as additional input to the trained machine learning model, the set of first metrology measurement values for the first set of substrates.

19. The non-transitory computer readable storage medium of claim 15, wherein a respective modification to the process recipe satisfies the drift criterion for the second set of substrates in response to a determination that the respective modification is predicted to cause an amount of drift of a predicted estimated set of metrology measurement values for the second set of substrates to be below a threshold amount.

20. The non-transitory computer readable storage medium of claim 15, wherein updating the process recipe based on the respective modification comprises at least one of modifying an operation of the process recipe or generating an instruction to terminate execution of the process recipe for the second set of substrates.
